(19) United States
(12) Patent Application Publication
(10) Pub. No.: US 2013/0341071 A1
(43) Pub. Date: Dec. 26, 2013

(54) TRANSPARENT CONDUCTIVE FILM

(71) Applicant: Carestream Health, Inc., Rochester, NY (US)

(72) Inventor: Matthew T. Stebbins, Woodbury, MN (US)

(73) Assignee: Carestream Health, Inc., Rochester, NY (US)

(21) Appl. No.: 13/905,380

(22) Filed: May 30, 2013

Related U.S. Application Data
(60) Provisional application No. 61/664,268, filed on Jun. 26, 2012.

(51) Int. Cl. H05K 1/02

(52) U.S. Cl. CPC H05K 1/0274; B82Y 99/00
USPC 174/253; 977/932

(57) ABSTRACT

Transparent conductive films are disclosed and claimed that exhibit high light transmittance, low surface resistance, and superior peel-off adhesion. Such films are useful in electronics applications.

### CROSS REFERENCE TO RELATED APPLICATIONS

This application claims the benefit of U.S. Provisional Application No. 61/664,268, filed Jun. 26, 2012, entitled TRANSPARENT CONDUCTIVE FILM, which is hereby incorporated by reference in its entirety.

### SUMMARY

At least one embodiment comprises a transparent conductive film comprising at least one transparent substrate; at least one transparent primer layer disposed on the at least one transparent substrate, where the at least one transparent primer layer is formed from at least one transparent primer layer coating mix comprising at least one hydroxy-functional polymer and at least one heat curable monomer; and at least one transparent conductive layer disposed on the at least one transparent primer layer, where the at least one transparent conductive layer is formed from at least one transparent conductive layer coating mix comprising at least one first cellulose ester polymer and at least one metal nanowire.

In at least some embodiments, the at least one transparent substrate comprises at least one polyester.

In at least some embodiments, the at least one transparent substrate comprises at least one first polyester comprising at least about 70 wt % ethylene terephthalate repeat units.

In at least some such embodiments, the at least one first hydroxy-functional polymer comprises a cellulose ester polymer, a polyether polyol, a polyester polyol, or a polyvinyl alcohol.

In at least some of the above embodiments, the at least one first hydroxy-functional polymer comprises a cellulose acetate polymer, a cellulose acetate butyrate polymer, or a cellulose acetate propionate polymer.

In at least some the above embodiments, the at least one first hydroxy-functional polymer comprises a cellulose acetate butyrate polymer.

In at least some the above embodiments, the at least one first hydroxy-functional polymer comprises a hydroxyl content of at least about 1 wt %, or at least about 3 wt %, or about 4.8 wt %, according to ASTM D817-96.

In at least some the above embodiments, the at least one heat curable monomer comprises at least about three ether groups.

In at least some the above embodiments, the at least one heat curable monomer comprises at least one melamine monomer.

In at least some the above embodiments, the at least one heat curable monomer comprises hexamethyoxymethylmelamine.

In at least some the above embodiments, the at least one first cellulose ester polymer comprises a cellulose acetate polymer, a cellulose acetate butyrate polymer, or a cellulose acetate propionate polymer.

In at least some the above embodiments, the at least one first cellulose ester polymer comprises a cellulose acetate butyrate polymer.

In at least some the above embodiments, the at least one metal nanowire comprises at least one silver nanowire.

In at least some the above embodiments, the transparent conductive film exhibits a four-point surface resistivity less than about 100 ohms/square.

In at least some the above embodiments, the transparent conductive film exhibits a peel-off adhesion value of 5, according to ASTM D3359-92A.

These embodiments and other variations and modifications may be better understood from the description, exemplary embodiments, examples, and claims that follow. Any embodiments provided are given only by way of illustrative example. Other desirable objectives and advantages inherently achieved may occur or become apparent to those skilled in the art.

### DESCRIPTION

All publications, patents, and patent documents referred to in this document are incorporated by reference in their entirety, as though individually incorporated by reference.

U.S. Provisional Application No. 61/664,268, filed Jun. 26, 2012, entitled TRANSPARENT CONDUCTIVE FILM, is hereby incorporated by reference in its entirety.

Transparent conductive films (TCFs) featuring conductive layers comprising silver nanowires and cellulose ester polymers are disclosed in U.S. Patent Application Publication 2012/0107600, TRANSPARENT CONDUCTIVE FILMS COMPRISING CELLULOSE ESTERS, published May 3, 2012, which is hereby incorporated by reference in its entirety. Such TCFs can exhibit high light transmittance and low surface resistance. However, it has been a challenge to develop TCFs that retain these properties, while also exhibiting superior peel-off adhesion.

### Transparent Conductive Films

Transparent and electrically conductive films have been used extensively in recent years in applications of touch panel display, liquid crystal display, electroluminescent lighting, organic light-emitting diode device, photovoltaic solar cell. Indium tin oxide (ITO) based transparent conductive film has been the transparent conductor-of-choice for most applications until recently due to its high conductivity, transparency, and relatively good stability. However, indium tin oxide based transparent conductive films have limitation due to the high cost of indium, the need for complicated and expensive vacuum deposition equipment and processes, and its inherent brittleness and tendency to crack, especially when indium tin oxide is deposited on flexible substrates.

Two important parameters for measuring the properties of transparent conductive films (TCFs) are total light transmittance (% T) and film surface electric conductivity. Higher light transmittance allows clear picture quality for display applications, higher efficiency for lighting and solar energy conversion applications. Lower resistivity is most desirable for most transparent conductive films applications in which power consumption can be minimized.

### Transparent Substrates

Some embodiments provide a TCF comprising at least one transparent substrate. The substrate may be rigid or flexible.

Suitable rigid substrates include, for example, glass, polycarbonates, acrylics, and the like.

When coating mixes for the various layers of the TCF are coated onto a flexible substrate, the substrate is preferably a flexible, transparent polymeric film that has any desired thickness and is composed of one or more polymeric materials. The substrate is required to exhibit dimensional stability during coating and drying of the conductive layer and to have suitable adhesive properties with overlying layers. Useful polymeric materials for making such substrate include polyesters (such as polyethylene terephthalate and polyethylene naphthalate), cellulose acetate and other cellulose esters, polyvinyl acetal, polyolefins, polycarbonates, and polystyrenes. Preferred substrates are composed of polymers having good heat stability, such as polyesters and polycarbonates. Support materials may also be treated or annealed to reduce shrinkage and promote dimensional stability. Transparent multilayer substrates can also be used.

At least some embodiments provide transparent conductive films comprising transparent substrates that comprise at least one polyester. The at least one polyester may, for example, comprise at least about 70 wt % ethylene terephthalate repeat units. Or it may comprise at least about 75 wt %, or at least about 80 wt %, or at least about 85 wt %, or at least about 90 wt % or at least about 95 wt % ethylene terephthalate repeat units.

Such polyesters may, for example, be made through condensation polymerization of one or more monomers comprising acid or ester moieties with one or more monomers comprising alcohol moieties. Non-limiting examples of monomers comprising acid or ester moieties include, for example, aromatic acids or esters, aliphatic acids or esters, and non-aromatic cyclic acids or esters. Exemplary monomers comprising acid or ester moieties include, for example, terephthalic acid, dimethyl terephthalate, isophthalic acid, dimethyl isophthalate, phthalic acid, methyl phthalate, trimellitic acid, trimethyl trimellitate, naphthalene dicarboxylic acid, dimethyl naphthalate, adipic acid, dimethyl adipate, azelaic acid, dimethyl azelate, sebacic acid, dimethyl sebacate, and the like. Exemplary monomers comprising alcohol moieties include, for example, ethylene glycol, propanediol, butanediol, hexanediol, neopentyl glycol, diethylene glycol, cyclohexanedimethanol, and the like.

Such polyesters may, for example, comprise repeat units comprising a first residue from a monomer comprising acid or ester moieties joined by an ester linkage to a second residue from a monomer comprising alcohol moieties. Exemplary repeat units are, for example, ethylene terephthalate, ethylene isophthalate, ethylene naphthalate, diethylene terephthalate, diethylene isophthalate, diethylene naphthalate, cyclohexylene terephthalate, cyclohexylene isophthalate, cyclohexylene naphthalate, and the like. Such polyesters may comprise more than one type of repeat group and may sometimes be referred to as copolyesters.

### Transparent Primer Layers

Some embodiments provide a TCF comprising at least one transparent primer layer disposed on the at least one transparent substrate, where the at least one transparent primer layer is formed from at least one transparent primer layer coating mix comprising at least one hydroxyl-functional polymer and at least one heat curable monomer. Such primer layers may, in some cases, be referred to as carrier layers, intermediate layers, adhesion promoter layers, interlayers, and the like. Such primer layers serve to promote the adhesion of the at least one transparent conductive layer to the at least one transparent substrate.

Hydroxy-functional polymers are polymers comprising hydroxyl groups that are capable of reacting with reactive groups on heat curable monomers, such as, for example, ether groups, to form covalent bonds. Examples of hydroxy-functional polymers include, for example, cellulose ester polymers, polyether polyols, polyester polyols, polyvinyl alcohols, and the like.

Cellulose ester polymers include cellulose acetates, such as, for example, cellulose acetate, cellulose triacetate, cellulose propionate, cellulose acetate propionate, cellulose acetate butyrate (CAB), and the like.

Hydroxy-functional polymers may be characterized by their hydroxyl content, expressed as a weight percentage, as determined by the ASTM D817-96 test method. Particularly useful hydroxy-functional polymers comprise hydroxyl contents of at least about 1 wt %, or at least about 3 wt%, or about 4.8 wt %. An exemplary hydroxy-functional polymer is CAB 533-0.4 cellulose acetate butyrate polymer, available from Eastman Chemical Company, Kingsport, Tenn., which has a hydroxyl content of 4.8 wt %, based on typical average lots.

Heat curable monomers are known. These may, for example, include monomers with one or more ether groups, such as, one, two, three, or more ether groups. Such ether groups may, for example, include one or more methoxy, ethoxy, or other groups. Such ether groups may react with other functional groups, such as, for example, hydroxyl groups, or they may react with other ether groups. Such reactions may result in polymerization or cross-linking. Heat curable monomers with aromatic or heteroaromatic rings, such as, for example, functionalized melamine monomers, may provide improved coating compatibility with such substrates as polyethylene terephthalate or polyethylene naphthalate. Hexamethoxymethylmelamine is an exemplary heat curable monomer.

Transparent primer layer coating mixes may also include thermal initiators, to promote polymerization and cross-linking reactions. An exemplary initiator is para-toluene sulfonic acid.

Transparent primer layers coating mixes may generally include organic solvents. These may be used for such purposes as controlling solution viscosity, improving wetting and substrate coating, and the like. Examples of organic solvents include ketones, esters, and alcohols, such as, for example, methyl ethyl ketone, butyl acetate, ethanol, and the like.

Transparent primer layers may be formed by coating the transparent primer layer coating mixes onto the transparent substrate using various coating procedures as wire wound rod coating, dip coating, air knife coating, curtain coating, slide coating, solid-die coating, roll coating, gravure coating, or extrusion coating. Such coating mixes may, for example, have between 6 and 20 wt % solids and between 5 and 30 cps viscosity at room temperature.

Such coatings may be dried after application to provide coating layers with thicknesses of, for example, between 100 and 500 nm. For example, two minute drying in a 280° F. (138° C.) oven is demonstrated in the examples.

### Transparent Conductive Layers

Some embodiments provide a TCF comprising at least one transparent conductive layer disposed on the at least one transparent primer layer, where the at least one transparent conductive layer is formed from at least one transparent conductive layer coating mix comprising at least one first cellulose ester polymer and at least one metal nanowire.

Suitable transparent conductive layer coating mixes are disclosed in U.S. Patent Application Publication 2012/0107600, TRANSPARENT CONDUCTIVE FILMS COMPRISING CELLULOSE ESTERS, published May 3, 2012, which is hereby incorporated by reference in its entirety.

For a practical manufacturing process for transparent conductive films, it is desirable and important to have both the conductive components, such as silver nanowires, and a polymer binder in a single coating solution. The polymer binder solution serves a dual role, as dispersant to facilitate the dispersion of silver nanowires and as a viscosifier to stabilize the silver nanowire coating dispersion so that the sedimentation of silver nanowires does not occur at any point during the coating process. This simplifies the coating process, and allows for a one-pass coating, and avoids the method of first coating bare silver nanowires to form a weak and fragile film that is subsequently over-coated with a polymer to form the transparent conductive film.

In order for a transparent conductive film to be useful in various device applications, it is also important that the binder of the transparent conductive film to be optically transparent and flexible; yet have high mechanical strength, hardness, and good thermal and light stability. It is also desirable that polymer binders for transparent conductive film contain functional groups having N, O, S or other elements with lone pair electrons to provide good coordination bonding for stabilization of silver nanowires during the dispersion and coating of silver nanowire and polymer solution.

Therefore, it is advantageous to use polymer binders having a high oxygen content, such as hydroxyl groups and carboxylate groups. These polymers have a strong affinity for the silver nanowire surface and facilitate the dispersion and stabilization of silver nanowires in the coating solution. Most oxygen-rich polymers also have the added benefit of having good solubility in the polar organic solvents commonly used to prepare organic solvent-coated thin films.

Cellulose ester polymers, such as cellulose acetate butyrate (CAB), cellulose acetate (CA), or cellulose acetate propionate (CAP) are superior to other oxygen-rich polymer binders when used to prepare silver nanowire based transparent conductive films, and coated from organic solvents, such as 2-butanone (methyl ethyl ketone, MEK), methyl iso-butyl ketone, acetone, methanol, ethanol, 2-propanol, ethyl acetate, or mixtures thereof. Their use results in transparent conductive films in which both the light transmittance and electrical conductivity of the coated films are greatly improved. In addition, these cellulose ester polymers have glass transition temperatures of at least 100° C., can form transparent and flexible films having high mechanical strength and hardness, and have high thermal and light stability. In contrast, similarly prepared transparent conductive films employing polyurethane or polyvinyl butyral polymeric binders show less desirable transmittance and conductivity.

The cellulose ester polymers are present in from about 40 to about 90 wt% of the dried transparent conductive films. Preferably, they are present in from about 60 to about 85 wt% of the dried films.

In some constructions, up to 50 wt % of the cellulosic ester polymer can be replaced by one or more additional polymers. These polymers should be compatible with the cellulosic polymer. By compatible is meant that the polymers form a transparent, single phase mixture when dried. The additional polymer or polymers can provide further benefits such as promoting adhesion to the support and improving hardness and scratch resistance. As above, total wt % of all polymers is from about 50 to about 90 wt % of the dried transparent conductive films. Preferably, the total weight of all polymers is from about 70 to about 85 wt % of the dried films. Polyester and polyacrylic polymers are examples of useful additional polymers.

Metal nanowires, such as, for example, silver or copper nanowires, are essential component for imparting electrical conductivity to the conductive films, and to the articles prepared using the conductive films. The electrical conductivity of the transparent conductive film is mainly controlled by a) the conductivity of a single nanowire, b) the number of nanowires between the terminals, and c) the connectivity between the nanowires. Below a certain nanowire concentration (also referred as the percolation threshold), the conductivity between the terminals is zero, as there is no continuous current path provided because the nanowires are spaced too far apart. Above this concentration, there is at least one current path available. As more current paths are provided, the overall resistance of the layer will decrease. However, as more current paths are provided, the percent of light transmitted through the conductive film decreases due to light absorption and scattering by the nanowires. Also, as the amount of metal nanowires in the conductive film increases, the haze of the transparent film increases due to light scattering by the metal nanowires. Similar effects will occur in transparent articles prepared using the conductive films.

In one embodiment, the metal nanowires have aspect ratio (length/width) of from about 20 to about 3300. In another embodiment, the metal nanowires have an aspect ratio (length/width) of from about 500 to 1000. Metal nanowires having a length of from about 5 μm to about 100 μm (micrometer) and a width of from about 30 nm to about 200 nm are useful. Metal nanowires having a width of from about 50 nm to about 120 nm and a length of from about 15 μm to about 100 μm are also useful for construction of a transparent conductive network film.

Metal nanowires can be prepared by known methods in the art. In particular, silver nanowires can be synthesized through solution-phase reduction of a silver salt (e.g., silver nitrate) in the presence of a polyol (e.g., ethylene glycol or propylene glycol) and poly(vinyl pyrrolidone). Large-scale production of silver nanowires of uniform size can be prepared according to the methods described in, e.g., Ducamp-Sanguesa, C. et al, J. of Solid State Chemistry, (1992), 100, 272-280; Sun, Y. et al., Chem. Mater. (2002), 14, 4736-4745; and Sun, Y. et al., Nanoletters, (2003), 3(7), 955-960.

Transparent conductive layer coating mixes may generally include organic solvents. These may be used for such purposes as controlling solution viscosity, improving wetting and substrate coating, and the like. Examples of organic solvents include toluene, 2-butanone (methyl ethyl ketone, MEK), methyl iso-butyl ketone, acetone, methanol, ethanol, 2-propanol, ethyl acetate, propyl acetate, ethyl lactate, or tetrahydrofuran, or mixtures thereof. Methyl ethyl ketone is a particularly useful coating solvent.

Transparent conductive layers may be formed by coating the transparent conductive layer coating mixes onto the transparent primer layers using various coating procedures wire wound rod coating, dip coating, air knife coating, curtain coating, slide coating, slot-die coating, roll coating, gravure coating, or extrusion coating. Surfactants and other coating aids can be incorporated into the coating formulation. Such coating mixes may, for example, have between 6 and 20 wt % solids and between 5 and 30 cps viscosity at room temperature.

Such coatings may be dried after application to provide coating layers with thicknesses of, for example, between 100 and 500 nm. For example, two minute drying in a 280° F. (138° C.) oven is demonstrated in the examples.

### Transparent Conductive Film Properties

Upon coating and drying, the transparent conductive film should have a surface resistivity of less than 1,000 ohms/sq, or less than 500 ohms/sq, or less than 100 ohms/sq, as measured using an R-CHEK model RC2175 surface resistivity meter, available from Electronic Design to Market, Inc, Toledo, OH.

Upon coating, and drying, the transparent conductive film should have as high a % transmittance as possible. A transmittance of at least 70% is useful. A transmittance of at least 80% and at least 90% are even more useful.

Upon coating and drying, the transparent conductive film should exhibit exceptional pull-off adhesion properties, such as a “5” rating when evaluated according to ASTM D3359-92A. Such a procedure is described in Example 1.

### EXEMPLARY EMBODIMENTS

U.S. Provisional Application No. 61/664,268, filed Jun. 26, 2012, entitled TRANSPARENT CONDUCTIVE FILM, which is hereby incorporated by reference in its entirety, disclosed the following 17 non-limiting exemplary embodiments:

A. A transparent conductive film comprising:

at least one transparent substrate;

at least one transparent primer layer disposed on the at least one transparent substrate, the at least one transparent primer layer formed from at least one transparent primer layer coating mix comprising at least one hydroxy-functional polymer and at least one heat curable monomer; and

at least one transparent conductive layer disposed on the at least one transparent primer layer, the at least one transparent conductive layer formed from at least one transparent conductive layer coating mix comprising at least one first cellulose ester polymer and at least one metal nanowire.

B. The transparent conductive film according to embodiment A, wherein the at least one transparent substrate comprises at least one polyester.
C. The transparent conductive film according to any of embodiments A-B, wherein the at least one transparent substrate comprises at least one first polyester comprising at least about 70 wt % ethylene terephthalate repeat units.
D. The transparent conductive film according to any of embodiments A-B, wherein the at least one first hydroxy-functional polymer comprises a cellulose ester polymer, a polyether polyol, a polyester polyol, or a polyvinyl alcohol.
E. The transparent conductive film according to any of embodiments A-D, wherein the at least one first hydroxy-functional polymer comprises a cellulose acetate polymer, a cellulose acetate butyrate polymer, or a cellulose acetate propionate polymer.
F. The transparent conductive film according to any of embodiments A-E, wherein the at least one first hydroxy-functional polymer comprises a cellulose acetate butyrate polymer.
G. The transparent conductive film according to any of embodiments A-F, wherein the at least one first hydroxy-functional polymer comprises a hydroxyl content of at least about 1 wt %, according to ASTM D817-96.
H. The transparent conductive film according to any of embodiments A-G, wherein that at least one first hydroxy-functional polymer comprises a hydroxyl content of at least about 3 wt %, according to ASTM D817-96.
J. The transparent conductive film according to any of embodiments A-H, wherein the at least one first hydroxy-functional polymer comprises a hydroxyl content of about 4.8 wt %, according to ASTM D817-96.
K. The transparent conductive film according to any of embodiments A-J, wherein the at least one heat curable monomer comprises at least about three ether groups.
L. The transparent conductive film according to any of embodiments A-K, wherein the at least one heat curable monomer comprises at least one melamine monomer.
M. The transparent conductive film according to any of embodiments A-L, wherein the at least one heat curable monomer comprises hexamethyoxymethylmelamine.
N. The transparent conductive film according to any of embodiments A-M, wherein the at least one first cellulose ester polymer comprises a cellulose acetate polymer, a cellulose acetate butyrate polymer, or a cellulose acetate propionate polymer.
P. The transparent conductive film according to any of embodiments A-N, wherein the at least one first cellulose ester polymer comprises a cellulose acetate butyrate polymer.
Q. The transparent conductive film according to any of embodiments A-P, wherein the at least one metal nanowire comprises at least one silver nanowire.
R. The transparent conductive film according to any of embodiments A-Q, exhibiting a four-point surface resistivity less than about 100 ohms/square.
S. The transparent conductive film according to any of embodiments A-R, exhibiting a peel-off adhesion value of 5, according to ASTM D3359-92A.

### EXAMPLES

### Example 1 (Comparative)

A silver layer coating mix was prepared by blending 54 parts by weight of a 1.85 wt % dispersion of silver nanowires in isopropanol, 3 parts by weight of a cellulose acetate butyrate polymer (CAB 381-20, Eastman Chemical), 33 parts by weight propyl acetate, and 10 parts by weight ethyl lactate. The mix had between 3 and 8 wt % solids and between 30 and 150 cps viscosity at room temperature.

A coated sample was then prepared. Several milliliters of the silver layer coating mix were applied to the top edge of a chrome gravure printing plate, which was engraved with a 200-500 line screen. A 5-7 mil polyethylene terephthalate (PET) film was wrapped onto an ethylene propylene diene monomer (EPDM) based rubber impression roller, which was then rolled from the top edge towards the bottom edge of the printing plate, transferring ink from the gravure recesses onto the PET film. The coated film was then placed in a 280° F. (138° C.) oven for two minutes. The dry silver layer thickness was between 100 and 500 nm.

The coated film's surface resistance was evaluated after it had cooled from the oven. The four-point surface resistance of the coated side of the film was measured using an R-CHEK device. The sample exhibited a surface resistance of 48 ohms/sq.

The coated film's peel-off adhesion was then evaluated according to ASTM D3359-92A. The coated side of each film was scribed with a razor blade and gently removing the debris with a lint-free cotton pad. Adhesive tape (#610 semi-transparent pressure-sensitive tape from 3M Company, St. Paul, Minn.) was then applied to the crosshatched area and smoothed with a rubber roller until there were no air bubbles between the tape and the coated film. The tape was then rapidly peeled off. The appearance of the coated film was given a score on a 0 to 5 scale: 5=edges of scribed cuts completely smooth; 4=flakes of coating detached at some intersections of scribed lines, with less than about 5% of the test area being affected; 3=flakes of coating detached along some edges and at some intersections of scribed lines, with about 5 to 15% of the test area being affected; 2=flakes of coating detached along some edges of scribed lines and on parts of the squares, with about 15 to 35% of the test area being affected; 1=coating detached along the edges of scribed lines in large ribbons, with more than about 35% of the test area being affected; 0=coating completely removed. Films attaining a score of 5 were given a rating of “PASS,” while films attaining a score less than 5 were given a rating of “FAIL.” This sample's appearance was rated as a “FAIL.”

### Example 2 (Comparative)

A primer layer coating mix was prepared by blending 12 parts by weight of a linear saturated thermoplastic polyester polymer (VITEL® 2200, Bostik) and 88 parts by weight methyl ethyl ketone. The mix had between 6 and 20 wt % solids and between 5 and 30 cps viscosity at room temperature.

A silver layer coating mix was prepared by blending 54 parts by weight of a 1.85 wt % dispersion of silver nanowires in isopropanol, 3 parts by weight of a cellulose acetate butyrate polymer (CAB 381-20, Eastman Chemical), 33 parts by weight propyl acetate, and 10 parts by weight ethyl lactate. The mix had between 3 and 8 wt % solids and between 30 and 150 cps viscosity at room temperature.

A coated sample was then prepared. The primer layer coating mix was applied to a 5-7 mil PET film using a gravure benchtop proofer. The coated film was then placed in a 280° F. (138° C.) oven for two minutes. The dry primer layer thickness was between 100 and 500 nm.

The silver layer coating mix was then applied to the primer layer of the coated PET film, using the method of Example 1. The dry silver layer thickness was between 100 and 500 nm.

The coated film's surface resistance was evaluated after it had cooled from the oven. The four-point surface resistance of the coated side of the film was measured using an R-CHEK device. The sample exhibited an infinite surface resistance.

The coated film's peel-off adhesion was then evaluated, using the method of Example 1. This sample's appearance was rated as a “PASS”.

### Example 3 (Inventive)

A primer layer coating mix was prepared by blending 6 parts by weight of a cellulose acetate butyrate polymer (CAB 553-0.4, Eastman Chemical), 6 parts by weight of hexamethoxymethylmelamine (CYMEL® 303, Cytec), 77.4 parts by weight methyl ethyl ketone, 10 parts by weight of butanol, and 0.6 parts by weight of para-toluene sulfonic acid. The mix had between 6 and 20 wt % solids and between 5 and 30 cps viscosity at room temperature.

A silver layer coating mix was prepared by blending 54 parts by weight of a 1.85 wt % dispersion of silver nanowires in isopropanol, 3 parts by weight of a cellulose acetate butyrate polymer (CAB 381-20, Eastman Chemical), 33 parts by weight propyl acetate, and 10 parts by weight ethyl lactate. The mix had between 3 and 8 wt % solids and between 30 and 150 cps viscosity at room temperature.

A coated sample was then prepared. The primer layer coating mix was applied to a 5-7 mil PET film using a gravure benchtop proofer. The coated film was then placed in a 280° F. (138° C.) oven for two minutes. The dry primer layer thickness was between 100 and 500 nm.

The silver layer coating mix was then applied to the primer layer of the coated PET film, using the method of Example 1. The dry silver layer thickness was between 100 and 500 nm.

The coated film's surface resistance was evaluated after it had cooled from the oven. The four-point surface resistance of the coated side of the film was measured using an R-CHEK device. The sample exhibited a surface resistance of 48 ohms/sq.

The coated film's peel-off adhesion was then evaluated, using the method of Example 1. This sample's appearance was rated as a “PASS”.

The invention has been described in detail with reference to particular embodiments, but it will be understood that variations and modifications can be effected within the spirit and scope of the invention. The presently disclosed embodiments are therefore considered in all respects to be illustrative and not restrictive. The scope of the invention is indicated by the appended claims, and all changes that come within the meaning and range of equivalents thereof are intended to be embraced therein.

What is claimed:

1. A transparent conductive film comprising:
at least one transparent substrate;
at least one transparent primer layer disposed on the at least one transparent substrate, the at least one transparent primer layer formed from at least one transparent primer layer coating mix comprising at least one hydroxy-functional polymer and at least one heat curable monomer; and
at least one transparent conductive layer disposed on the at least one transparent primer layer, the at least one transparent conductive layer formed from at least one transparent conductive layer coating mix comprising at least one first cellulose ester polymer and at least one metal nanowire.

2. The transparent conductive film according to claim 1, wherein the at least one transparent substrate comprises at least one polyester comprising at least about 70 wt % ethylene terephthalate repeat units.

3. The transparent conductive film according to claim 1, wherein the at least one first hydroxy-functional polymer comprises a cellulose acetate polymer, a cellulose acetate butyrate polymer, or a cellulose acetate propionate polymer.

4. The transparent conductive film according to claim 1, wherein that at least one first hydroxy-functional polymer comprises a hydroxyl content of at least about 3 wt %, according to ASTM D817-96.

5. The transparent conductive film according to claim 1, wherein the at least one first hydroxy-functional polymer comprises a hydroxyl content of about 4.8 wt %, according to ASTM D817-96.

6. The transparent conductive film according to a claim 1, wherein the at least one heat curable monomer comprises at least about three ether groups.

7. The transparent conductive film according to claim 1, wherein the at least one heat curable monomer comprises at least one melamine monomer.

8. The transparent conductive film according to claim 1, wherein the at least one heat curable monomer comprises hexamethyoxymethylmelamine.

9. The transparent conductive film according to claim 1, wherein the at least one first cellulose ester polymer comprises a cellulose acetate polymer, a cellulose acetate butyrate polymer, or a cellulose acetate propionate polymer.

10. The transparent conductive film according to claim 1, wherein the at least one metal nanowire comprises at least one silver nanowire.
